(19) United States
(12) Patent Application Publication
(10) Pub. No.: US 2024/0100648 A1
(43) Pub. Date: Mar. 28, 2024

(54) CHEMICAL MECHANICAL POLISHING PADS WITH A DISULFIDE BRIDGE

(71) Applicant: CMC Materials LLC, Aurora, IL (US)

(72) Inventors: Jaeseok Lee, Beaverton, OR (US); Jessica Lindsay, Aurora, IL (US); Satish Rai, Aurora, IL (US); Sangcheol Kim, Chicago, IL (US)

(21) Appl. No.: 18/371,246

(22) Filed: Sep. 21, 2023

Related U.S. Application Data
(60) Provisional application No. 63/409,086, filed on Sep. 22, 2022.

(51) Int. Cl. B24B 37/24

(52) U.S. Cl. CPC B24B 37/24; H01L 21/3212

(57) ABSTRACT

A precursor for preparing a chemical mechanical polishing pad includes a prepolymer, a disulfide-containing component, and a curative. The chemical mechanical polishing pad prepared from the precursor includes a disulfide bridge in a polymer matrix. The disulfide bridge may include a disulfide bond capable of undergoing a chain exchange reaction at temperatures experienced during chemical mechanical polishing processes, resulting in rearrangement of nearby disulfide bonds during the chemical mechanical polishing processes rather than breakage of these bonds.

### TECHNICAL FIELD

This disclosure generally relates to chemical mechanical polishing pads, and more specifically to chemical mechanical polishing pads with a disulfide bridge.

### BACKGROUND

An integrated circuit is typically formed on a substrate by the sequential deposition of conductive, semi-conductive, and/or insulative layers on a silicon wafer. A variety of fabrication processes require polishing or planarization of at least one of these layers on the substrate. For example, for certain applications (e.g., polishing of a metal layer to form vias, plugs, and lines in the trenches of a patterned layer), an overlying layer is planarized until the top surface of a patterned layer is exposed. In other applications (e.g., polishing of a dielectric layer for photolithography), an overlying layer is polished until a desired thickness remains over the underlying layer. Chemical-mechanical polishing (CMP) is one method of surface planarization. This method typically involves a substrate being mounted on a carrier head. The exposed surface of the substrate is typically placed against a polishing pad on a rotating platen. The carrier head provides a controllable load (e.g., a downward force) on the substrate to push it against the rotating polishing pad. A polishing liquid, such as slurry with abrasive particles, can also be disposed on the surface of the polishing pad during polishing.

### SUMMARY

CMP pads experience considerable thermal and mechanical stress during CMP processes. These stresses can cause breakdown of conventional CMP pad materials, resulting in decreased CMP pad lifetimes and decreased and/or inconsistent performance over time. This disclosure provides an improved CMP pad that is made of a material with a disulfide bridge in a polyurethane matrix. The disulfide bridge may include a disulfide bond capable of undergoing a chain exchange reaction at temperatures experienced during chemical mechanical polishing processes, resulting in rearrangement of nearby disulfide bonds during the chemical mechanical polishing processes rather than breakage of these bonds. The improved CMP pad has an improved lifetime and improved polishing performance under CMP conditions (i.e., at high temperature and high mechanical stress). The improved CMP pads of this disclosure may have improved material removal rates compared to those achieved by previous CMP pads, and these improved removal rates may be sustained during longer usages of the improved CMP pads.

In one embodiment, a precursor for preparing a chemical mechanical polishing pad includes a prepolymer, a disulfide-containing component, and a curative. Furthermore, the prepolymer may be a prepolymer of polyurethane. The prepolymer may include polyisocyanate. The prepolymer may include polytetra-hydrofuran and toluene diisocyanate. A percentage by mass of the prepolymer is in a range from 60% to 80%. The disulfide-containing component may include 2-hydroxyethyl disulfide. A percentage by mass of the disulfide component may be in a range from 2.5% to 7.5%. The curative may be dimethylthiotoluenediamine. The precursor may further include one or more pore fillers.

In another embodiment, a chemical mechanical polishing pad comprising a polishing surface, wherein the polishing surface comprises a material comprising a disulfide bridge in a polymer matrix. Additionally, the polymer matrix may be a polyurethane matrix. The material comprising the disulfide bridge may include a disulfide bond capable of undergoing a chain exchange reaction at temperatures experienced during chemical mechanical polishing processes, resulting in rearrangement of bonds during the chemical mechanical polishing processes.

In yet another embodiment, a method of preparing a chemical mechanical polishing pad includes steps of preparing a precursor by combining a prepolymer, a disulfide-containing component, and a curative; casting the precursor at a first temperature; and curing the cast precursor at a second temperature. Moreover, the method may further include, prior to casting the precursor, mixing the combined prepolymer, disulfide-containing component, and curative for less than 1 minute. The first temperature may be greater than the second temperature. The method may further include combining the prepolymer with one or more additives, such as a pore filler. Furthermore, the prepolymer may be a prepolymer of polyurethane. The prepolymer may include polyisocyanate. The prepolymer may include polytetra-hydrofuran and toluene diisocyanate. A percentage by mass of the prepolymer is in a range from 60% to 80%. The disulfide-containing component may include 2-hydroxyethyl disulfide. A percentage by mass of the disulfide component may be in a range from 2.5% to 7.5%. The curative may be dimethylthiotoluenediamine.

### BRIEF DESCRIPTION OF FIGURES

To assist in understanding the present disclosure, reference is now made to the following description taken in conjunction with the accompanying drawings, in which:

FIG. 1 is a diagram of an example system for chemical mechanical polishing (CMP);

FIG. 2 is a reaction diagram of an example reaction for preparing a CMP pad with a disulfide bridge and polyurethane matrix;

FIG. 3 is a reaction diagram of an example thermally induced transformation of the disulfide bridge containing components of the CMP pad during use of the CMP pad;

FIG. 4 is a block diagram of an example composition of a precursor for preparing a CMP pad that can be used in the system of FIG. 1;

FIG. 5 is a flowchart of an example process for preparing a CMP pad;

FIG. 6 is a plot of removal rates achieved by an improved CMP pad this disclosure and a previous CMP pad under different polishing conditions;

FIGS. 7 and 8 are graphs of removal rates achieved by different improved CMP pads of this disclosure using different polishing slurries; and

FIGS. 9 and 10 are plots of CMP pad temperature and torque, respectively, achieved during a polishing process using an improved CMP pad of this disclosure and a previous CMP pad.

### DETAILED DESCRIPTION

It should be understood at the outset that, although example implementations of embodiments of the disclosure are illustrated below, the present disclosure may be implemented using any number of techniques, whether currently known or not. The present disclosure should in no way be limited to the example implementations, drawings, and techniques illustrated below. Additionally, the drawings are not necessarily drawn to scale.

The present disclosure recognizes that conventional materials used to prepare CMP pads suffer from inadequate lifetimes due to CMP pad wear and degradation during their use in CMP processes. For instance, previous polyurethane-based CMP pads are worn out and degrade during the severe mechanical and thermal stress experienced CMP processes. High surface temperatures experienced during CMP processes can lead to breakdown of previous CMP pads, resulting in loss of performance and decreased usable lifetimes. This disclosure provides an improved CMP pad with self-healing properties. The CMP pads of this disclosure are prepared from a precursor that includes a disulfide-containing component along with a prepolymer and a curative. Disulfide bonds in the resulting material can undergo a chain exchange reaction at temperatures experienced during CMP processes resulting in rearrangement of bonds rather than breaking of bonds during CMP processes. This rearrangement facilitates improved CMP pad performance and lifetime.

### Chemical Mechanical Polishing (CMP) System

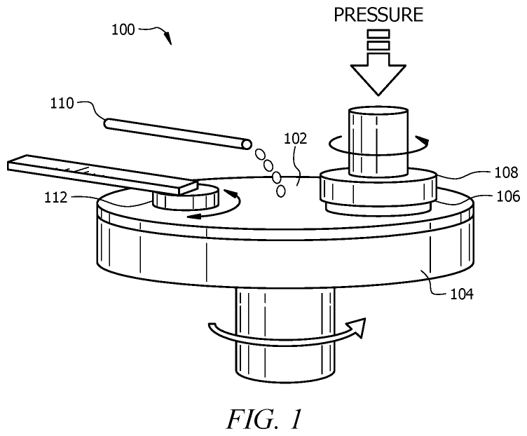

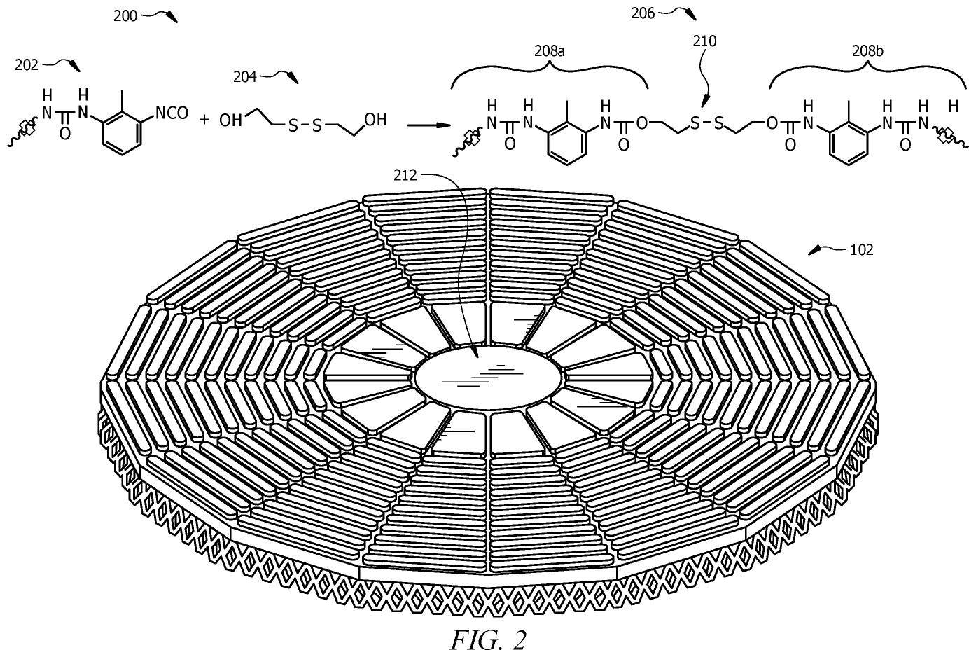

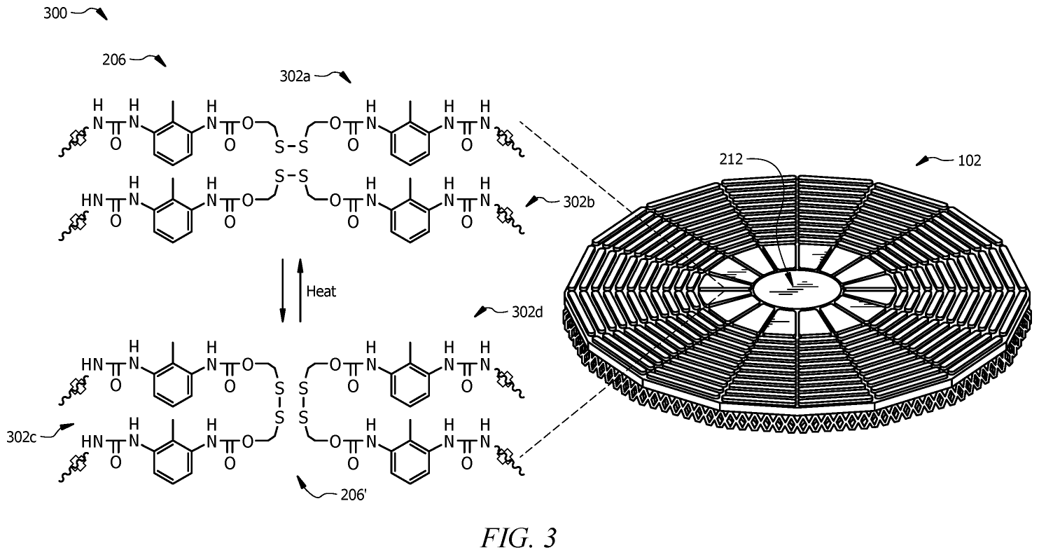

FIG. 1 illustrates a system 100 for performing chemical mechanical polishing. System 100 includes a CMP pad 102 (also referred to as a “polishing pad”) which is placed on or attached to a platen 104. For example, an adhesive layer (not shown) may be used to attach the polishing pad to the platen 104. The platen 104 can generally be rotated during chemical mechanical polishing. A wafer 106 (e.g., a silicon wafer with or without conductive, semi-conductive, and/or insulative layers, as described above) is attached to a head 108 of a rotatable chuck. The wafer 106 may be attached using vacuum and/or a reversible adhesive (e.g., an adhesive that holds the wafer 106 in place during chemical mechanical polishing but allows the wafer 106 to be removed from the head 108 after chemical mechanical polishing). As illustrated in FIG. 1, a pressure may be applied to the wafer 106 during chemical mechanical polishing (e.g., to facilitate contact between the surface of the wafer 106 and the CMP pad 102). As described further below, the improved CMP pad 102 of this disclosure may allow effective polishing with a decreased downward pressure applied. Example polishing pads 102 are illustrated in FIGS. 2 and 3, described

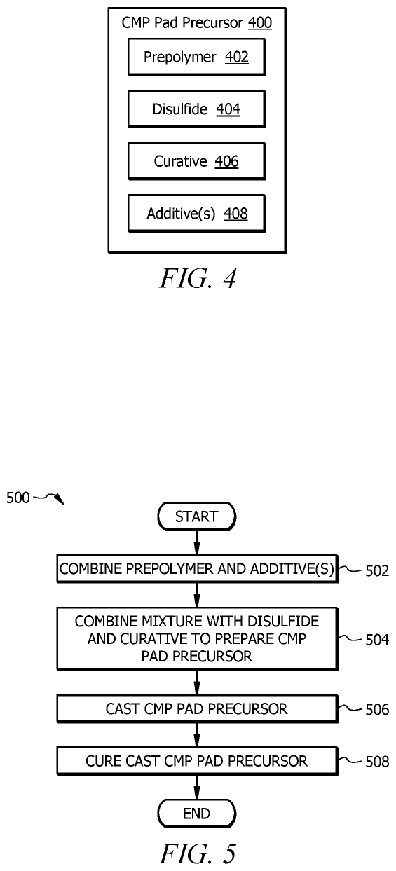

below, alongside chemical reactions associated with CMP pad 102 formation and resilience during use in a CMP process. Still referring to FIG. 1, the CMP pad 102 generally has a circular or approximately cylindrical shape (i.e., with a top surface, a bottom surface, and a curved edge). As described in greater detail with respect to FIGS. 2-10 below, at least a top polishing surface of the CMP pad 102 comprises a matrix of polyurethane chains connected by a disulfide bond. Example compositions of precursors used to prepare example polishing pads 102 are described in greater detail below with respect to FIGS. 2 and 4. CMP pad 102 may have any appropriate thickness and any appropriate diameter (e.g., to be employed with a CMP system such as system 100). For instance, the thickness of a CMP pad 102 may range from about 0.5 millimeters to greater than 5 centimeters. In some embodiments, the thickness of the polishing pad may be in a range from 1 millimeter to 5 millimeters. Any appropriate manufacturing processes may be used to prepare polishing pads 102, including, for example, cast-based manufacturing processes, additive-manufacturing processes, and the like. Polishing pad diameter may be selected to match or be just smaller than, the diameter of the platen 104 of the polishing system 100 used. The CMP pad 102 generally has a uniform thickness (e.g., a thickness that varies by no more than 50%, 25%, 20%, 10%, 5%, or less across the radial extent of the polishing pad).

A slurry 110 may be provided on the surface of the CMP pad 102 before and/or during chemical mechanical polishing. The slurry 110 may be any appropriate slurry for polishing of the wafer type and/or layer material to be planarized (e.g., to remove a silicon oxide layer from the surface of the wafer 106). The slurry 110 generally includes a fluid and abrasive and/or chemically reactive particles. Any appropriate slurry 110 may be used. For example, the slurry 110 may react with one or more materials being removed from a surface being planarized. The improved CMP pad 102 of this disclosure facilitates both a higher removal rate and longer lifetime even in more aggressive slurries, such as W8902-CI45, which can reach relative high temperatures during polishing.

A conditioner 112 is a device which is configured to condition the surface of the CMP pad 102. The conditioner 112 generally contacts the surface of the CMP pad 102 and removes a portion of the top layer of the CMP pad 102 to improve its performance during chemical mechanical polishing. For example, the conditioner 112 may roughen the surface of the CMP pad 102. Certain embodiments of the polishing pads described in this disclosure provide for decreased need for conditioning and improved resilience to repeated conditioning, such that CMP performance can be maintained with fewer or shorter conditioning steps and CMP pad lifetime is maintained even after multiple rounds of conditioning.

### Example CMP Pad

FIG. 2 shows an example CMP pad 102 in greater detail. The example CMP pad 102 includes a top polishing surface 212, which may include grooves and/or channels, which may facilitate movement of slurry (e.g., slurry 110 of FIG. 1) away from the surface 212 during a CMP process. At least the top polishing surface 212 includes a material 206 that comprises a matrix of a polymer 208a,b with a disulfide bridge 210. The disulfide bridge 210 is a sulfur-sulfur bond coupling chains of the polymer 208a,b, as illustrated in the example chemical structures shown in FIG. 2. As described further with respect to FIG. 3 below, the sulfur-sulfur bonds of the disulfide bridge 210 may undergo a reaction at increased temperature that improves the resiliency of the material 206, resulting in a self-healing CMP pad 102 with improved usable lifetime and performance

Material 206 may be prepared via reaction 200. In reaction 200, a prepolymer 202 reacts with a disulfide-containing component 204. The prepolymer 202 may be a polyisocyante, such as toluenediisocyante, as shown in the example of FIG. 2. The disulfide-containing component 204 may be 2-hydroxyethyl disulfide, as shown in the example of FIG. 2. Further details and examples of the components of a precursor for preparing CMP pad 102 are described below with respect to FIGS. 4 and 5.

FIG. 3 illustrates an example heat activated reaction of molecules 302a,b of the material 206 of an example CMP pad 102 during a CMP process. As described above, CMP pads, such as CMP pad 102, experience increased temperatures during CMP processes. Previous polymer CMP pad materials may break down at these increased temperatures (e.g., due at least in part to thermally induced bond breaking). In contrast, the disulfide bridges 210 of improved CMP pad material 206 impart self-healing properties to the CMP pad 102.

For example, as shown in the reaction 300 of FIG. 3, molecules 302a and 302b of the initial CMP pad material 206 may undergo a radical-mediated reaction involving hemolytic cleavage of the disulfide bridge 210 followed by subsequent radical transfer of sulfur radicals to form new molecules 302c and 302d of thermally rearranged material 206′. Thus, rather than breaking down, the molecules 302a,b transfer polymer chains to form similar molecules 302c and 302d, such that the structure of the CMP pad 102 undergoes less breakdown at increased temperatures. This may facilitate improved performance and increased usable lifetime of CMP pad 102 compared to previous CMP pads. For example, the microscale texture of the CMP pad 102 may be more effectively maintained at high temperatures because bonds are rearranged via reaction 300 rather than being broken. In some cases, the CMP pad 102 may be used to remove materials that involve high CMP temperatures, such as tungsten.

### Example CMP Pad Precursor

FIG. 4 shows an example precursor 400 for preparing a CMP pad 102. The precursor 400 includes a prepolymer 402, a disulfide-containing component 404, a curative 406, and optionally one or more additives 408. The precursor 400 is an example and may include more or fewer components to meet the needs of a given application.

The prepolymer 402 may be a curable polyurethane prepolymer. As an example, the prepolymer 402 may be a toluene diisocyanate (TDI) prepolymer. For example, the TDI prepolymer may be based on polytetrahydrofuran (PTMEG), polyester, or PTMEG/polyester. The prepolymer 402 may be a polyisocyante, such as toluenediisocyante. Examples of such a prepolymer 402 are Imuthane PET-75D available from Coim International and 80DPLF from Anderson Development Company. Another example prepolymer 402 is the prepolymer 202 of FIG. 2. In some cases, the precursor 400 includes between 60% to 80% of the prepolymer 402 by weight. However, prepolymer 402 may be added at a lower or higher concentration as appropriate for a given application.

The disulfide-containing component 404 is a component having a disulfide, or sulfur-sulfur, bond. An example disulfide-containing component is the disulfide-containing component 204 illustrated in FIG. 2, described above. For example, the disulfide-containing component may be 2-hydroxyethyl disulfide. In some cases, the precursor 400 includes between 2.5% to 7.5% of the disulfide-containing component 404 by weight. The precursor 400 may include between 3.5% to 6.5% of the disulfide-containing component 404 by weight. The precursor 400 may include between 5% to 6% of the disulfide-containing component 404 by weight. Examples of the disulfide-containing component 404 include, but are not limited to, allyl disulfide, 3,3′-dihydroxydiphenyl disulfide, 4-aminophenyl disulfide, penicillamine disulfide, bis(2-methacryloyl)oxyethyl disulfide, bis(16-hydroxy-hexadecyl) disulfide. 4-nitrophenyl disulfide, bis(4-methoxyphenyl) disulfide, bis(10-carboxydecyl) disulfide, 2-(salicylideneamino)phenyl disulfide, and N,N′-bis(2-hydroxy-benzylidene)-4-aminophenyl disulfide.

The curative 406 is used to initiate the polymerization of the prepolymer 402. In some cases, the curative 406 may initiate or facilitate this reaction at an increased temperature. As an example, the curative 406 may be dimethylthiotoluenediamine (DMTDA). The precursor 400 may include between 5% to 20% of the curative 406 by weight. 10-20%. However, curative 406 may be added at a lower or higher concentration as appropriate for a given application. Examples of the curative 406 include, but are not limited to, diamines, such as 4,4′-methylene bis(ortho-chloro aniline), 2,6-diethyl-3-chloro aniline, 3,5-diethytoluene-2,4-diamine, 3,5-diethytoluene-2,6-diamine, and methylene bis(ortho-ethylaniline); and diols, such as hydroquinone bis (2-hydroxyethyl) ether, 1,4-butanediol, 2-methyl-1,3-propanediol, 1,3-propanediol, and 1,6 hexanediol.

The one or more additives 408 may include stabilizers, plasticizers, pore fillers, pigments, and the like. For example, pore fillers are particles (e.g., microspheres) which expand in volume when heated. Pore fillers may cause the formation of pores in the polishing pad, which may improve pad performance by creating a porous structure in the polymer matrix formed by the cured prepolymer 402. Another example additive 408 is carbon black, a substance for adding color to the formed CMP pad 102. The additives 408 are typically added at a weight percentage of between 1% to 30%. For example, additives may be included at between 1% and 5% by weight. However, the additives 408 may be added at a lower or higher concentration as appropriate for a given application. In some cases, the precursor 400 does not include additives 408.

### Example Method of Preparing CMP Pads

FIG. 5 illustrates an example process 500 for preparing a CMP pad 102 according to an illustrative embodiment of the present disclosure. Process 500 may begin at step 502 where the prepolymer 402 is combined with one or more additives 408. For example, the prepolymer 402 and additive(s) 408 may be combined and mixed for a period of time. As an example, the prepolymer 402 and additive(s) 408 may be combined and mixed for about 2 hours at 160° F.

At step 504, the mixture from step 502 is combined with the disulfide-containing component 404 and the curative 406. The resulting mixture may be briefly mixed (e.g., for about 1 minute or less) before proceeding to step 506 where the resulting mixture (i.e., the precursor 400 of FIG. 4) is cast to prepare a CMP pad 102. As an example, the precursor 400 may be cast for about 10 minutes at 260° F.

At step 508, the cast precursor 400 is cured for a period time an appropriate temperature for curing the precursor 400. Curing at step 508 may be performed at the same or at a different temperature than the temperature used for casting at step 506. In some cases, curing may be performed at a lower temperature than is used for casting. For example, the cast precursor 400 may be cured for about 12 hours at 200° F. The resulting CMP pad 102 may be used for CMP pad processes as described with respect to the example of FIG. 1 above.

### Experimental Examples

Different example CMP pads (Samples 1-3) were prepared using the improved precursor of this disclosure, and their performance was compared to that of a control CMP pad. TABLE 1 below shows the compositions of the improved CMP pad Samples 1-3 and the control CMP pad. The prepolymer was PTMEG base TDI (Imuthane PET-75D from Coim International for the Control CMP pad and 80DPLF from Anderson Development Company for Samples 1-3). The disulfide-containing component was 2-hydroxyethyl disulfide from Sigma-Aldrich. The curative was DMTDA (Curene 107 from Anderson Development Company). The boron nitride powder additive was NX1 Powder 25 Lb Ctr from Momentive Performance Materials. The pore filler additive was Expancel 461 DE20 d70 from Nouryon Pulp and Performance Chemicals LLC.

TABLE 1
Compositions of precursors used to prepare tested CMP pad samples.

| | | | | Boron | |
|---|---|---|---|---|---|
| | | | | Nitride | Pore |
| | Pre- | | | Powder | Filler |
| Pad ID | polymer | Disulfide | Curative | Additive | Additive |
| Control | 77.4 wt % | 0.0 wt % | 18.7 wt % | 1.6 wt % | 2.3 wt % |
| Sample 1 | 79.5 wt % | 5.5 wt % | 12.1 wt % | 0.0 wt % | 2.9 wt % |
| Sample 2 | 78.3 wt % | 5.9 wt % | 13.1 wt % | 0.0 wt % | 2.7 wt % |
| Sample 3 | 77.1 wt % | 2.9 wt % | 17.2 wt % | 0.0 wt % | 2.8 wt % |

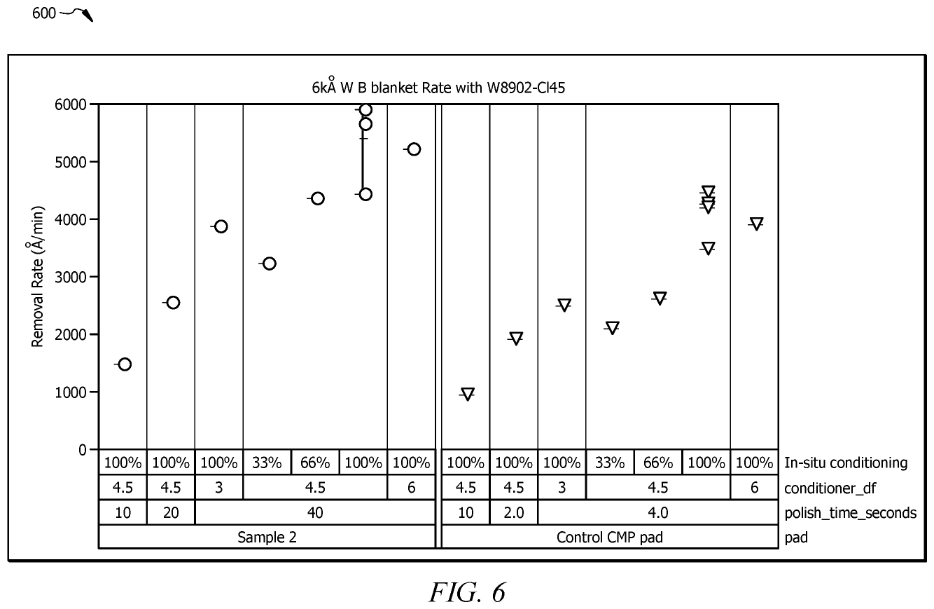

FIG. 6 shows a comparison of the removal rates for a 6 k Å tungsten (W) blanket layer achieved by the Sample 2 CMP pad and the control CMP pad under different conditions of amount of in situ conditioning (i.e., the relative duration of conditioning steps performed), conditioning downforce (“conditioner_df”, i.e., the force applied during conditioning in psi), and the polishing time in seconds. The Sample 2 CMP pad achieved a higher removal rate under milder conditioning conditions than those needed for the control CMP pad. As such, the Sample 2 CMP pad should provide improved performance over a longer CMP pad life, while also consuming less materials to perform conditioning steps (e.g., because conditioning steps can be shortened and/or performed less frequently).

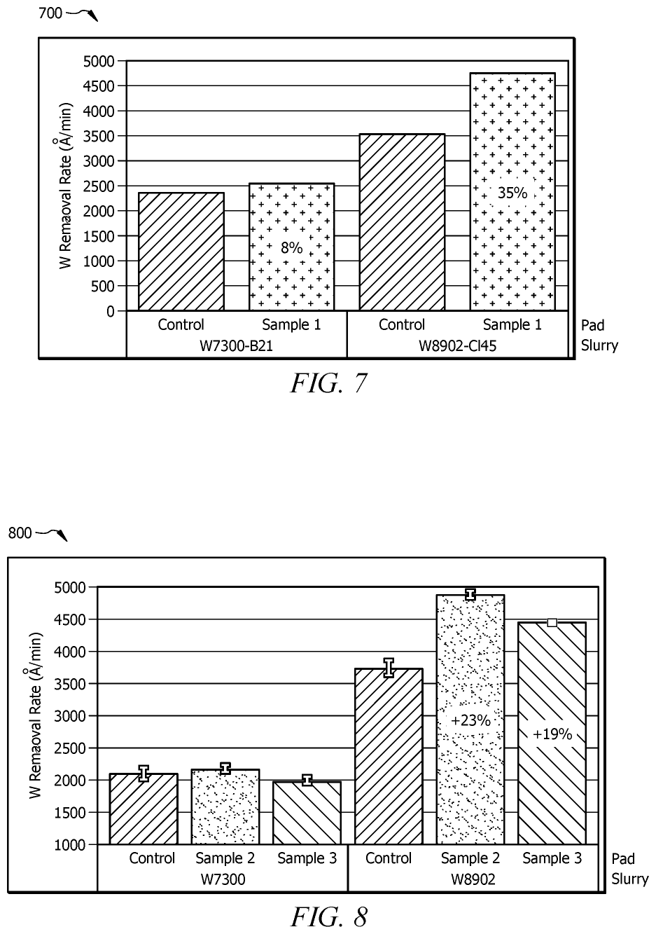

FIG. 7 shows the tungsten removal rates of the Sample 1 CMP pad and a control CMP pad in two different chemical-mechanical polishing slurries (W7300-B21 and W8902-CI45). W8902-CI45 is a more aggressive slurry that can remove tungsten more effectively but may also cause increased temperatures to be reached during polishing. As shown in FIG. 7, the Sample 1 CMP pad displayed a higher removal rate than the control CMP pad, particularly when the W8902-CI45 was used. This further demonstrates the improved performance of CMP pads of this disclosure for tungsten removal.

FIG. 8 shows the tungsten removal rates of Sample 2 and 3 CMP pads and a control CMP pad in the same two different chemical-mechanical polishing slurries (W7300-B21 and W8902-CI45). As shown in FIG. 8, the Sample 2 and 3 CMP pads displayed a higher removal rate than the control CMP pad when the W8902-CI45 was used.

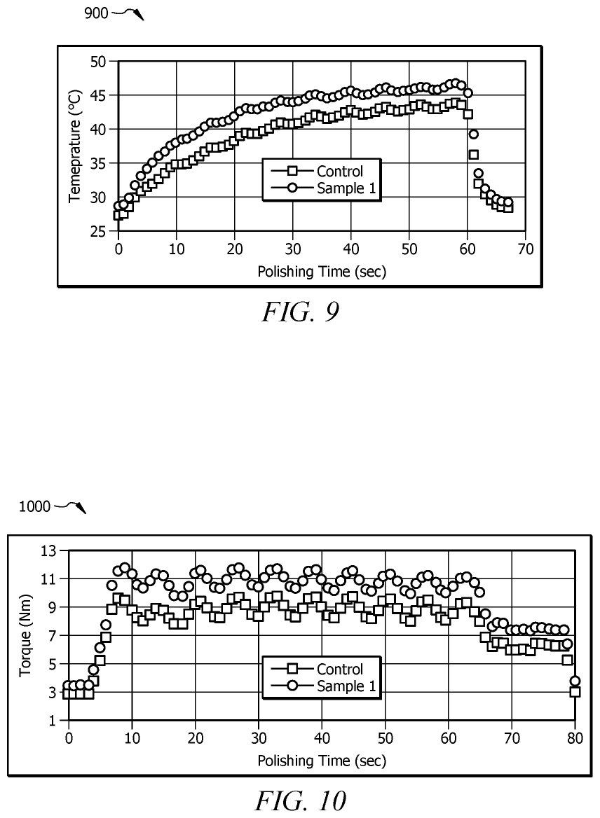

FIGS. 9 and 10 show the temperature and torques, respectively, achieved during a CMP process using the control CMP pad and the Sample 1 CMP pad for tungsten removal. The Sample 1 CMP pad was able to operate effectively at a higher temperature and torque than the control CMP pad. This ability to perform consistently and well at higher temperature and torque may be imparted at least partially by the self-healing properties of the CMP pads of this disclosure, as described, for example, with respect to FIG. 3 above.

Modifications, additions, or omissions may be made to the systems, apparatuses, and methods described herein. The components of the systems and apparatuses may be integrated or separated. Moreover, the operations of the systems and apparatuses may be performed by more, fewer, or other components. The methods may include more, fewer, or other steps. Additionally, steps may be performed in any suitable order. Additionally, operations of the systems and apparatuses may be performed using any suitable logic. As used in this document, “each” refers to each member of a set or each member of a subset of a set.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, feature, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative. Additionally, although this disclosure describes or illustrates particular embodiments as providing particular advantages, particular embodiments may provide none, some, or all of these advantages.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. The use of any and all examples, or exemplary language (e.g., “such as”) provided herein, is intended merely to better explain the disclosure and does not pose a limitation on the scope of claims.

What is claimed is:

1. A precursor for preparing a chemical mechanical polishing pad, the precursor comprising:
a prepolymer;
a disulfide-containing component; and
a curative.

2. The precursor of claim 1, wherein the prepolymer is a prepolymer of polyurethane.

3. The precursor of claim 1, wherein the prepolymer comprises polyisocyanate.

4. The precursor of claim 1, wherein the prepolymer comprises polytetrahydrofuran and toluene diisocyanate.

5. The precursor of claim 1, wherein a percentage by mass of the prepolymer is in a range from 60% to 80%.

6. The precursor of claim 1, wherein the disulfide-containing component comprises 2-hydroxyethyl disulfide.

7. The precursor of claim 1, wherein a percentage by mass of the disulfide component is in a range from 2.5% to 7.5%.

8. The precursor of claim 1, wherein the curative is dimethylthiotoluenediamine.

9. The precursor of claim 1, further comprising one or more pore fillers.

10. A chemical mechanical polishing pad comprising a polishing surface, wherein the polishing surface comprises a material comprising a disulfide bridge in a polymer matrix.

11. The chemical mechanical polishing pad of claim 10, wherein the polymer matrix is a polyurethane matrix.

12. The chemical mechanical polishing pad of claim 10, wherein the material comprising the disulfide bridge includes a disulfide bond capable of undergoing a chain exchange reaction at temperatures experienced during chemical mechanical polishing processes resulting in rearrangement of bonds during the chemical mechanical polishing processes.

13. A method of preparing a chemical mechanical polishing pad, the method comprising:
preparing a precursor by combining a prepolymer, a disulfide-containing component, and a curative;
casting the precursor at a first temperature; and
curing the cast precursor at a second temperature.

14. The method of claim 13, further comprising, prior to casting the precursor, mixing the combined prepolymer, disulfide-containing component, and curative for less than one (1) minute.

15. The method of claim 13, wherein the first temperature is greater than the second temperature.

16. The method of claim 13, wherein the prepolymer comprises polyisocyanate.

17. The method of claim 13, wherein a percentage by mass of the prepolymer is in a range from 60% to 80%.

18. The method of claim 13, wherein the disulfide-containing component comprises 2-hydroxyethyl disulfide.

19. The method of claim 13, wherein a percentage by mass of the disulfide component is in a range from 2.5% to 7.5%.

20. The method of claim 13, wherein the curative is dimethylthiotoluenediamine.
